(19) United States
(12) Patent Application Publication
(10) Pub. No.: US 2026/0082559 A1
(43) Pub. Date: Mar. 19, 2026

(54) 3D MEMORY DEVICE

(71) Applicant: MACRONIX International Co., Ltd., Hsinchu (TW)

(72) Inventor: Chih-Kai Yang, Kaohsiung City (TW)

(73) Assignee: MACRONIX International Co., Ltd., Hsinchu (TW)

(21) Appl. No.: 18/888,157

(22) Filed: Sep. 18, 2024

(51) Int. Cl. H10B 43/27

(52) U.S. Cl. CPC H10B 43/27

(57) ABSTRACT

A 3D memory device including a stacked structure, a first group of channel structures and a second group of channel structures, a partition structure and at least one support structure is provided. The stacked structure includes a plurality of conductive layers and a plurality of dielectric layers stacked alternately. A top surface of the stacked structure is parallel to a plane defined by a first direction and a second direction. The first group of channel structures and the second group of channel structures penetrate the stacked structure and are arranged along a first direction. The partition structure includes a plurality of discrete partition structures and is disposed between the first group of channel structures and the second group of channel structures. The plurality of discrete partition structures are arranged along the second direction and penetrate the stacked structure. At least one support structure is disposed between the adjacent discrete partition structures. The 3D memory device is a 3D NAND flash memory device with high capacity and performance.

### BACKGROUND

### Technical Field

The disclosure relates to a three-dimensional (3D) memory device.

### Description of Related Art

In the 3D memory device, as the number of stacked layers of composite film stacks in the stacked structure increases, the bending phenomenon of composite film stacks with high aspect ratios becomes more severe. The severe bending phenomenon may even cause a short circuit between the bit line and the top word line, thereby affecting the operation of the 3D memory device.

In order to solve the above problem, the slit (the place where the separation structure is located) disposed between the two groups of channel structures is divided into a plurality of sub-slits with a spacing in the existing 3D memory device. The mechanical strength of the existing 3D memory device is strengthened, thereby reducing the bending phenomenon of the stacked structure in the 3D memory device. However, during the formation of the plurality of conductive layers, the mechanical strength of the plurality of dielectric layers located between adjacent sub-slits is reduced due to the removal of the plurality of sacrificial layers. The dielectric layers with the reduced mechanical strength prone to collapse, resulting in reduced reliability of the existing 3D memory device.

### SUMMARY

The disclosure provides a 3D memory device having the relatively high reliability.

The 3D memory provided by one embodiment of the disclosure includes a stacked structure, a first group of channel structures and a second group of channel structures, a partition structure and at least one support structure is provided. The stacked structure includes a plurality of conductive layers and a plurality of dielectric layers stacked alternately. A top surface of the stacked structure is parallel to a plane defined by a first direction and a second direction. The first group of channel structures and the second group of channel structures penetrate the stacked structure and are arranged along a first direction. The partition structure includes a plurality of discrete partition structures and is disposed between the first group of channel structures and the second group of channel structures. The plurality of discrete partition structures are arranged along the second direction and penetrate the stacked structure. At least one support structure is disposed between the adjacent discrete partition structures.

The 3D memory provided by another embodiment of the disclosure includes a first stacked structure and a second stacked structure, a first group of channel structures and a second group of channel structures, a separation structure and at least one support structure is provided. The first stacked structure includes a source line plane. The second stacked structure is disposed over the first stacked structure and includes a plurality of conductive layers and a plurality of dielectric layers stacked alternately. The first group of channel structures and the second group of channel structures penetrate the stacked structure and arranged along a first direction. The separation structure includes a first partition structure and a second partition structure. The first partition structure includes a plurality of discrete partition structures disposed between the first group of channel structures and the second group of channel structures, wherein the plurality of discrete partition structures are arranged along a second direction different from the first direction and penetrate the second stacked structure. The second partition structure continuously extends along the second direction and penetrates the second stacked structure, wherein the second partition structure and the first partition structure are parallel along the first direction. The at least one support structure is disposed between the adjacent discrete partition structures.

Based on the above, in the 3D memory device provided by one embodiment of the disclosure, the at least one support structure is disposed between the adjacent discrete partition structures. Therefore, the plurality of dielectric layers located between the adjacent discrete partition structures can have a stable structure, which makes the 3D memory device of the disclosure have relatively high reliability.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of a 3D memory device according to an embodiment of the disclosure.

FIG. 1B shows an enlarged top view of a first embodiment of an array region according to FIG. 1A.

FIGS. 2A to 2D are schematic cross-sectional views of a manufacturing method of the 3D memory device along a cross-section line A-A′ in FIG. 1B.

FIGS. 3A to 3D are schematic cross-sectional views of a manufacturing method of the 3D memory device along a cross-section line B-B′ in FIG. 1B.

FIGS. 4A to 4D are schematic cross-sectional views of a manufacturing method of the 3D memory device along a cross-section line C-C′ in FIG. 1B.

FIG. 5A shows an enlarged top view of a second embodiment of an array region according to FIG. 1A.

FIG. 5B shows an enlarged top view of a third embodiment of an array region according to FIG. 1A.

FIG. 6 shows an enlarged top view of a fourth embodiment of an array region according to FIG. 1A.

### DESCRIPTION OF THE EMBODIMENTS

The following examples are listed and described in detail with accompanying drawings, but the provided examples are not intended to limit the scope of the disclosure. In addition, the drawings are for illustrative purposes only and are not drawn to original size. To facilitate understanding, the same elements will be identified with the same symbols in the following description.

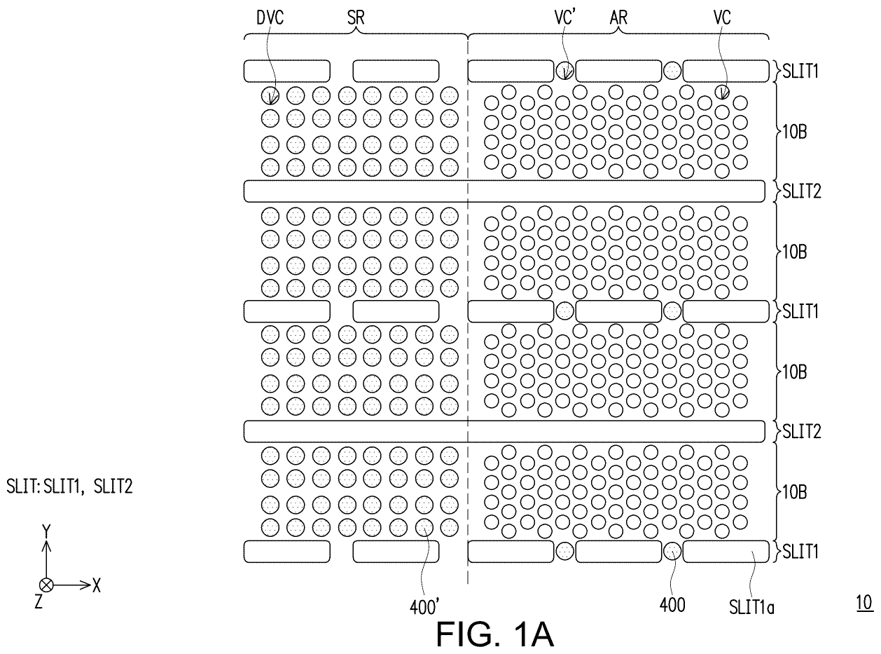

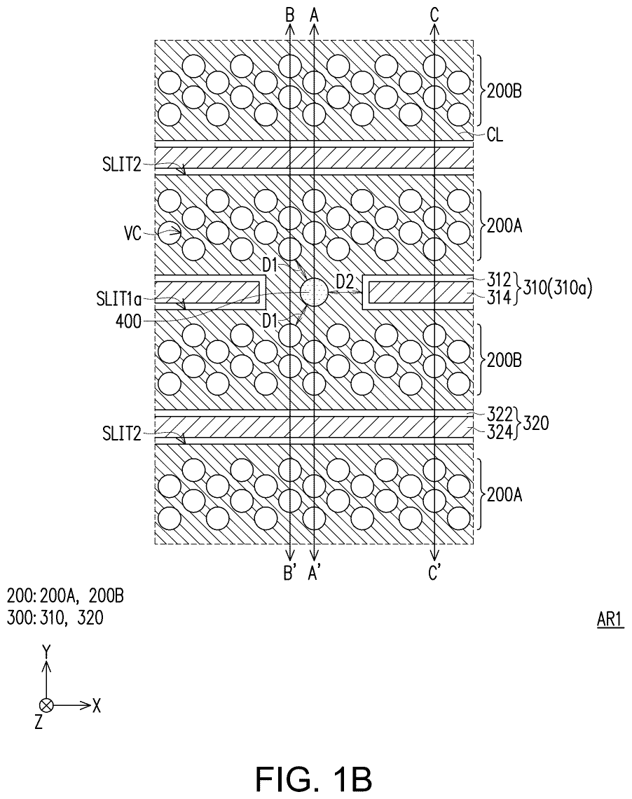

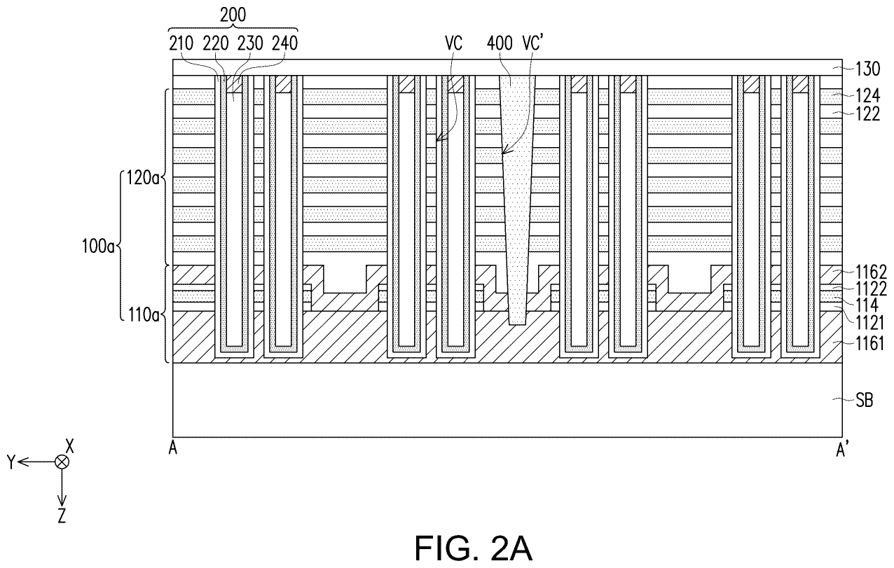

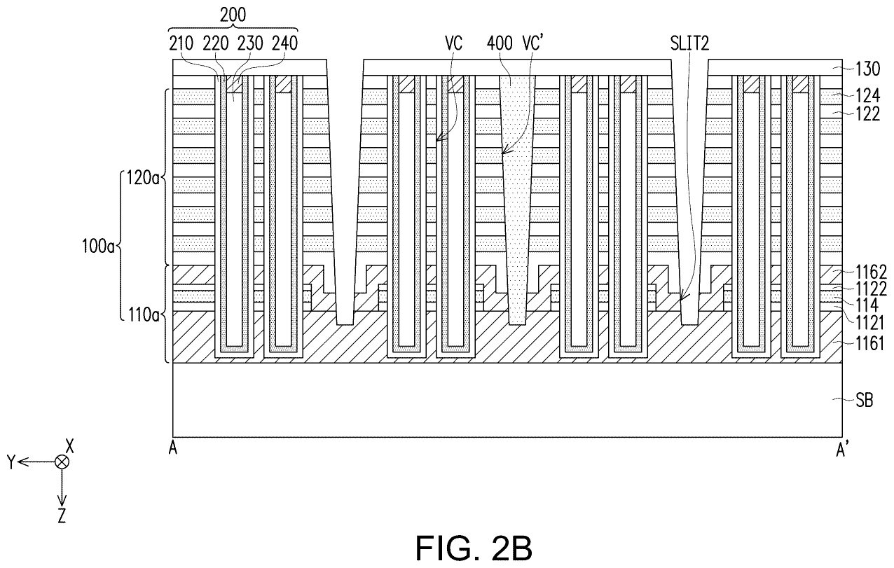

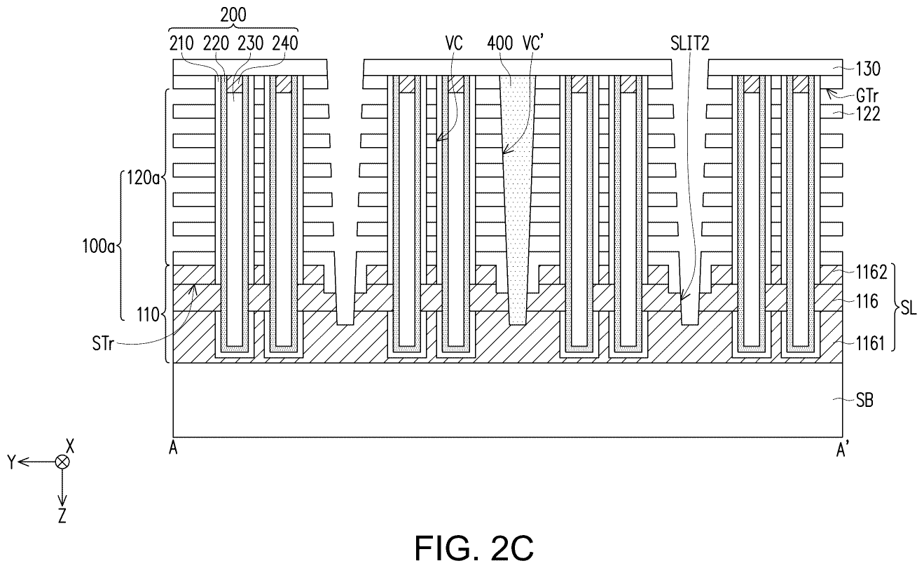

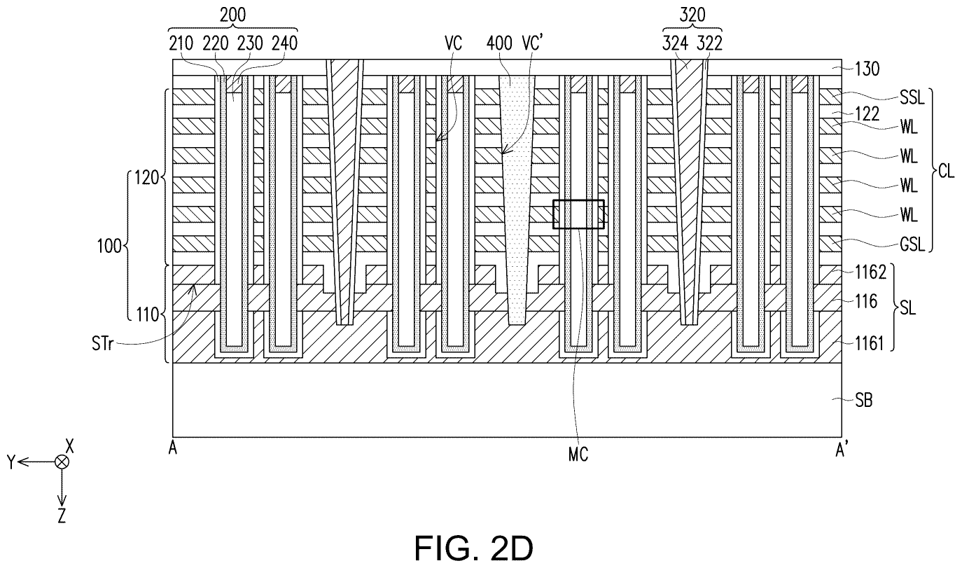

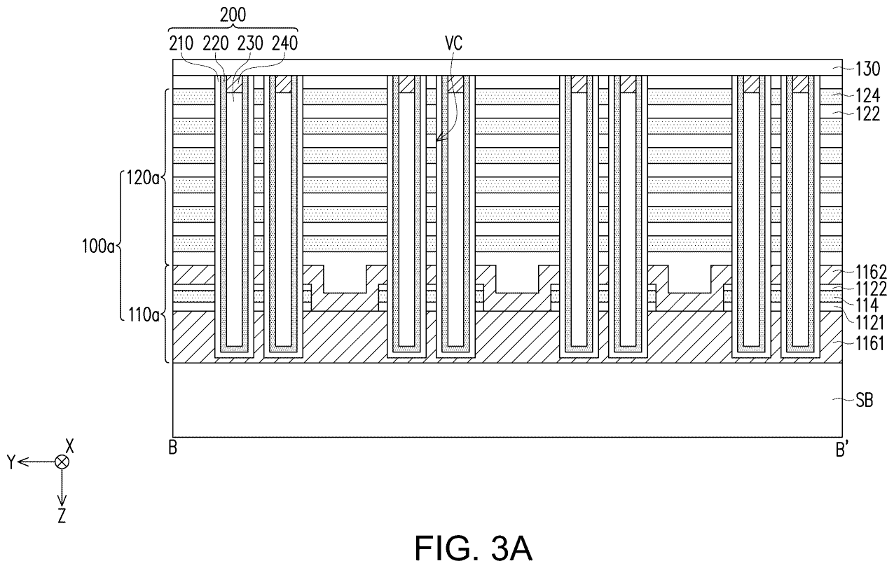

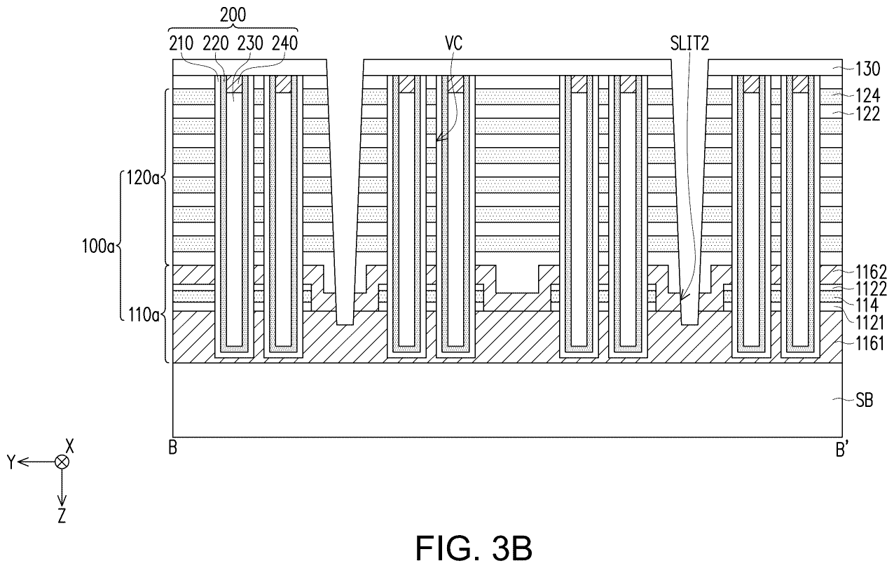

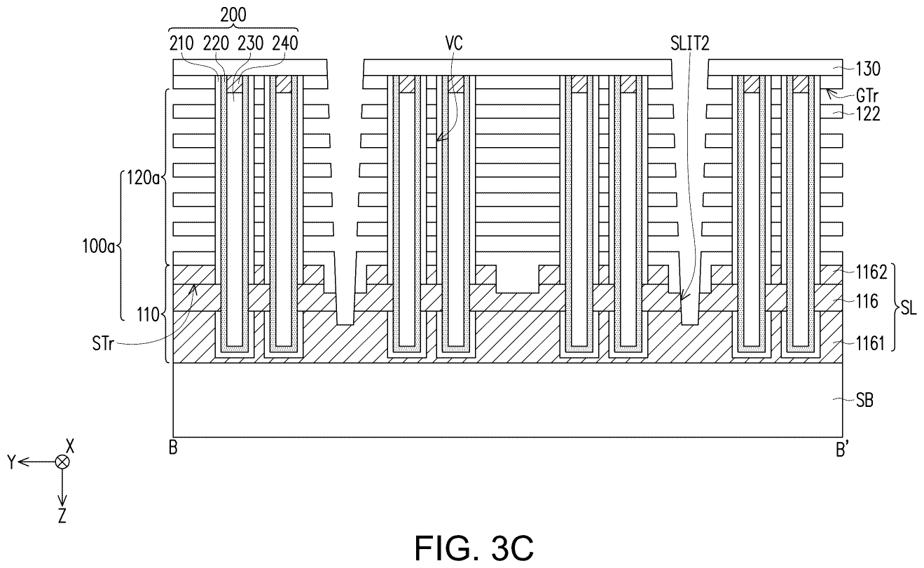

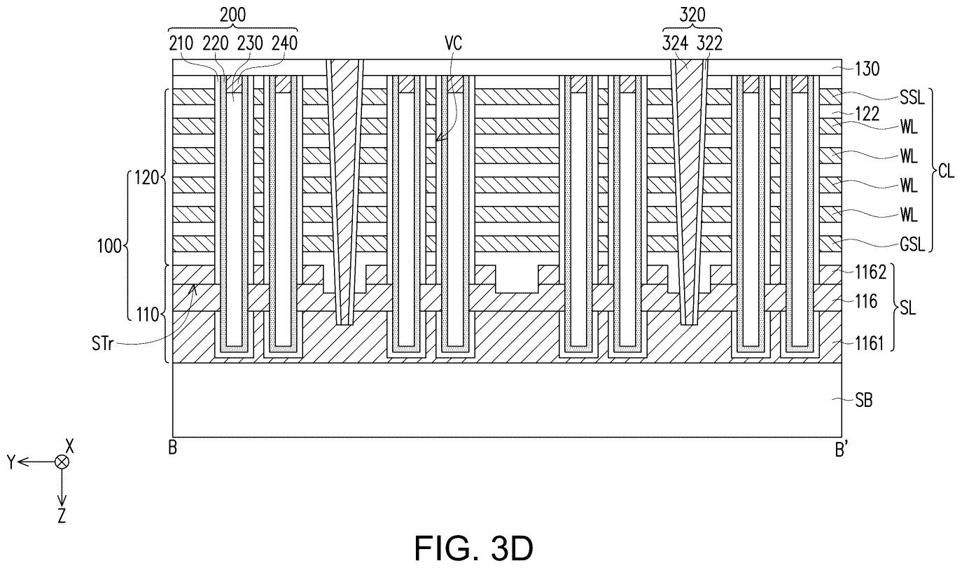

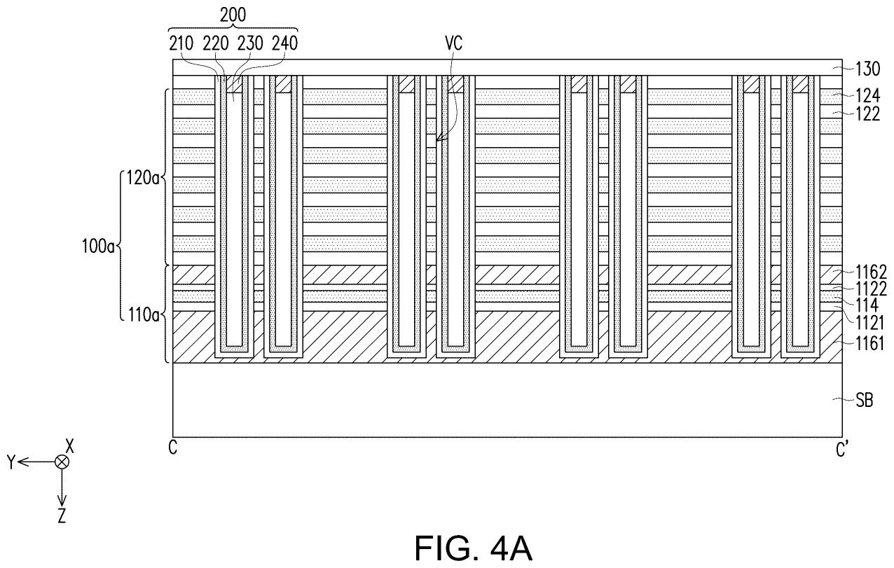

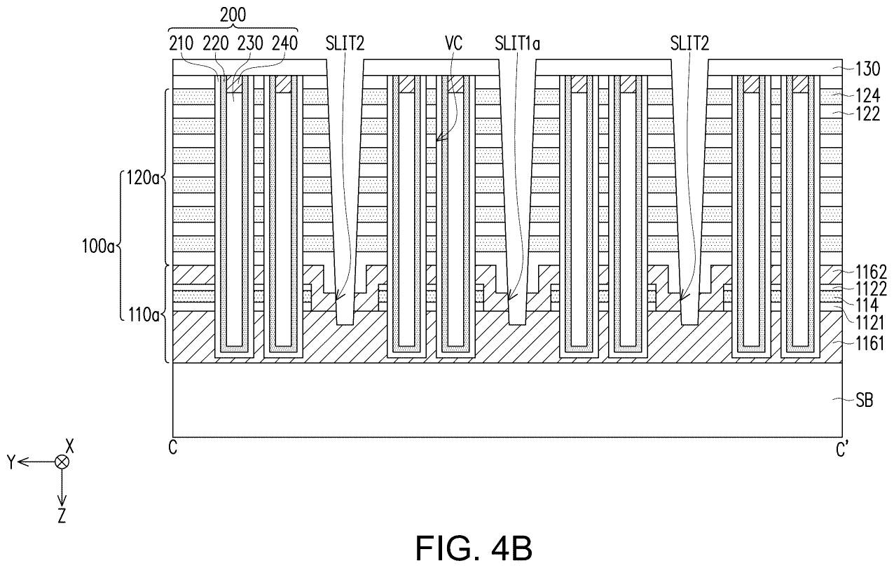

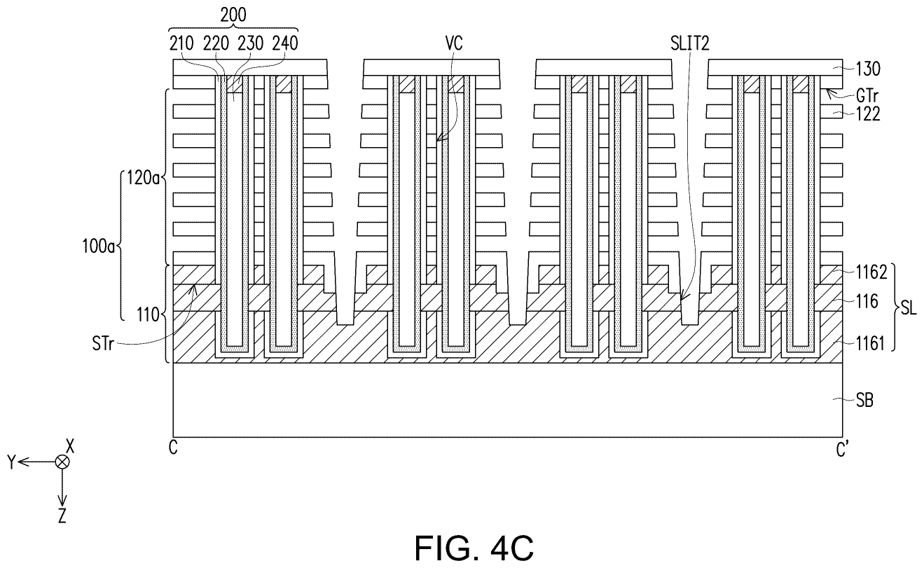

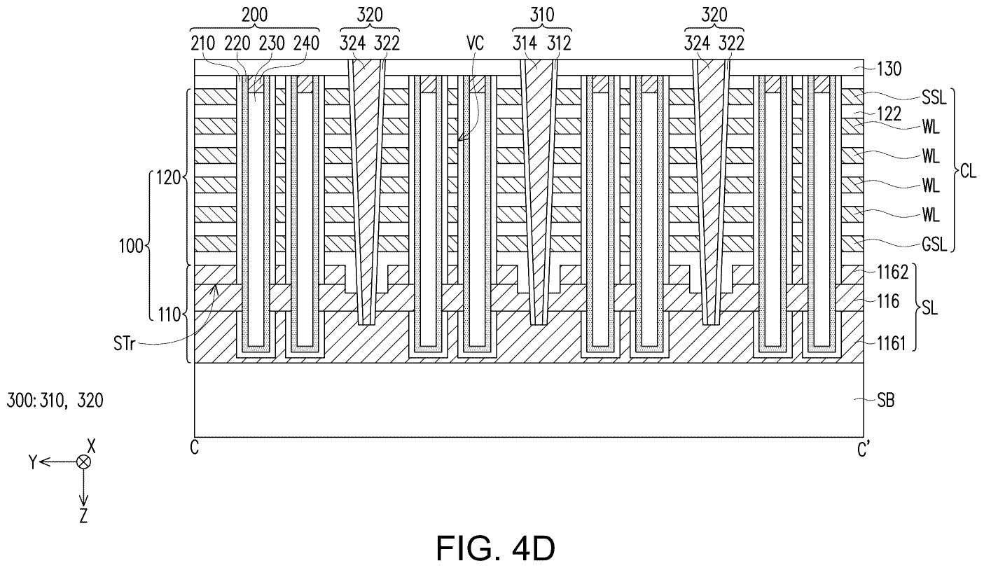

FIG. 1A is a schematic top view of a 3D memory device according to an embodiment of the disclosure. FIG. 1B shows an enlarged top view of a first embodiment of an array region AR1 according to FIG. 1A. FIGS. 2A to 2D are schematic cross-sectional views of a manufacturing method of the 3D memory device along a cross-section line A-A′ in FIG. 1B. FIGS. 3A to 3D are schematic cross-sectional views of a manufacturing method of the 3D memory device along a cross-section line B-B′ in FIG. 1B. FIGS. 4A to 4D are schematic cross-sectional views of a manufacturing method of the 3D memory device along a cross-section line C-C′ in FIG. 1B.

Referring to FIGS. 1A, 1B, 2A, 3A, and 4A simultaneously, a stacked architecture layer 100a including a channel structure 200 and at least one support structure 400 is provided. In some embodiments, the stacked architecture layer 100a is disposed above a substrate SB. The substrate SB can be a semiconductor substrate. In some embodiments, a material of the substrate SB can include silicon, doped silicon, germanium, silicon germanium, semiconductor compounds, other suitable semiconductor materials, or combinations thereof. For example, the substrate SB can be a silicon substrate, but the disclosure is not limited thereto. In some embodiments, a plurality of doping regions can be formed in the substrate SB in accordance with the design requirements. For example, the plurality of doping regions including a P-type well region (not shown) and an N-type deep well region (not shown) can be formed in the substrate SB, but the disclosure is not limited thereto. In other embodiments, a buried oxide layer (not shown) can be formed on the substrate SB.

In the present embodiment, the stacked architecture layer 100a includes a first stacked structure layer 110a and a second stacked structure layer 120a. The second stacked structure layer 120a is disposed on the first stacked structure layer 110a.

In some embodiments, a method of forming the first stacked structure layer 110a includes the following steps, but the disclosure is not limited thereto. First, a chemical vapor deposition process or other suitable processes is performed to form a first conductive layer 1161 over the substrate SB. Next, a chemical vapor deposition process or other suitable processes is performed to form a first insulator 1121, a first sacrificial layer 114 and a second insulator 1122 on the first conductive layer 1161 in this sequence. After that, a chemical vapor deposition process or other suitable processes is performed to form a second conductive layer 1162 on the second insulator 1122. In some embodiments, a material of the first conductive layer 1161 and the second conductive layer 1162 includes polysilicon, a material of the first insulator 1121 and the second insulator 1122 includes silicon oxide, and a material of the first sacrificial layer 114 includes silicon nitride, but the disclosure is not limited thereto.

In some embodiments, a method of forming the second stacked structure layer 120a includes the following steps, but the disclosure is not limited thereto. First, a chemical vapor deposition process or other suitable processes is performed to form a dielectric layer 122 on the first stacked structure layer 110a. Next, a chemical vapor deposition process or other suitable processes is performed to form a second sacrificial layer 124 on the dielectric layer 122. After that, the above steps are repeated to form a plurality of the dielectric layers 122 and a plurality of the second sacrificial layers 124 alternately stacked in a direction Z (a direction perpendicular to a top view plane defined by directions X and Y) on the first stacked structure layer 110a. In some embodiments, a material of the dielectric layer 122 includes silicon oxide, and a material of the second sacrificial layer 124 includes silicon nitride, but the disclosure is not limited thereto. In the present embodiment, a topmost layer of the second stacked structure layer 120a is a topmost layer of the plurality of dielectric layers 122, but the disclosure is not limited thereto.

In some embodiments, a method of forming the channel structure 200 in the stacked architecture layer 100a includes the following steps, but the disclosure is not limited thereto.

### Step (1): Forming a Plurality of Channel Holes VC

In some embodiments, a portion of the stacked architecture layer 100a is removed by performing a patterning process to form the plurality of channel holes VC in the stacked architecture layer 100a. The patterning process can include a photolithography process and an etching process, but the disclosure is not limited thereto. The plurality of channel holes VC at least penetrate the second stacked structure layer 120a in the direction Z, and extend to the first stacked structure layer 110a to expose a portion of the first conductive layer 1161, but the disclosure is not limited thereto.

### Step (2): Forming the Channel Structure 200 in the Plurality of Channel Holes VC

In the present embodiments, the channel structure 200 includes a charge storage structure 210, a channel layer 220, an insulating pillar 230 and a conductive plug 240. The insulating pillar 230 extends along the direction Z. The conductive plug 240 is disposed on the insulating pillar 230. The channel layer 220 surrounds the insulating pillar 230 and the conductive plug 240. The charge storage structure 210 surrounds the channel layer 220. In some embodiments, a method of forming the channel structure 200 includes the following steps, but the disclosure is not limited thereto.

### Step (2-1): Forming the Charge Storage Structure 210

First, a tunneling material layer (not shown), a charge storage material layer (not shown) and a blocking material layer (not shown) are sequentially and conformally formed on the second stacked structure layer 120a by performing a suitable deposition process. The tunneling material layer, the charge storage material layer and the blocking material layer are formed in the plurality of channel holes VC. Next, an etching process is performed to remove the tunneling material layer, the charge storage material layer and the blocking material layer located on the top surface of the second stacked structure layer 120a. The remaining tunneling material layer, and the remaining charge storage material layer and the remaining blocking material layer are conformally disposed in the plurality of channel holes VC. Hence, the charge storage structure 210 including a tunneling layer (not shown), a charge storage layer (not shown), and a blocking layer (not shown) is formed. In some embodiments, the charge storage structure 210 includes a composite layer of oxide-nitride-oxide (ONO). In detail, a material of the tunneling layer may include silicon oxide. A material of the charge storage layer may include silicon nitride. A material of the blocking layer may include silicon oxide, but the disclosure is not limited thereto.

### Step (2-2): Forming the Channel Layer 220

First, a channel material layer (not shown) is conformally formed over the second stacked structure layer 120a by performing a suitable deposition process and an annealing process. The channel material layer is formed in each of the plurality of channel holes VC. Next, an etching process is performed to remove the channel material layer located over the top surface of the second stacked structure layer 120a. The remaining channel material layer is conformally disposed in the plurality of channel holes VC, and the channel layer 220 is formed. In some embodiments, a material of the channel layer 220 can include doped semiconductor material or undoped semiconductor material. For example, the material of the channel layer 220 include polysilicon, but the disclosure is not limited thereto.

### Step (2-3): Forming the Insulating Pillar 230

First, an insulating material layer (not shown) is formed over the second stacked structure layer 120a by performing a suitable deposition process. The insulating material layer is filled in the plurality of channel holes VC. Next, the insulating material layer located on the top surface of the second stacked structure layer 120a is removed and a portion of the insulating material layer located in each channel hole VC is removed by performing an etch-back process and/or a planarization process. A portion of the channel layer 220 on sidewalls of the channel holes VC is exposed. The insulating pillar 230 is formed in each of the plurality of channel holes VC. In some embodiments, a material of the insulating pillar 230 includes silicon oxide.

### Step (2-4): Forming the Conductive Plug 240

First, a top portion of the insulating pillar 230 is removed and an interior surface of the channel layer 220 at a top of the second stacked structure layer 120a is exposed. Then, a conductive plug material layer (not shown) is formed over the second stacked structure layer 120a by performing a suitable deposition process. The conductive plug material layer is filled in the channel holes VC. Next, a planarization process is performed to remove the conductive plug material layer located on the top surface of the second stacked structure layer 120a. Hence, the conductive plug 240 is formed in each of the plurality of channel holes VC. The conductive plug 240 electrically connects to the channel layer 220. In some embodiments, a material of the conductive plug 240 includes polysilicon, metal, or a combination thereof, but the disclosure is not limited thereto.

At this point, the forming of channel structure 200 is completed. Although the manufacturing method of the channel structure 200 of the present embodiment is explained by taking the above method as an example, the manufacturing method of the channel structure 200 provided by the disclosure is not limited thereto. In the present embodiment, the channel structure 200 can be divided into multiple groups of channel structures in accordance with the relationship between locations. For example, as shown in FIG. 1B, the channel structure 200 may include a first group of channel structures 200A and a second group of channel structures 200B, and the first group of channel structures 200A and the second group of channel structures 200B may alternately disposed in a direction Y, but the disclosure is not limited thereto.

It is worth mentioned that an insulating liner (not shown) can be formed in the plurality of channel holes VC before forming the channel structure 200 in the plurality of channel holes VC, but the disclosure is not limited thereto.

In some embodiments, a method of forming the at least one support structure 400 in the stacked architecture layer 100a includes the following steps, but the disclosure is not limited thereto.

### Step (1′): Forming at Least One Through Hole VC′

In some embodiments, a portion of the stacked architecture layer 100a is removed by performing a patterning process to form the at least one through hole VC′ in the stacked architecture layer 100a. The patterning process can include a photolithography process and an etching process, but the disclosure is not limited thereto. The at least one through hole VC′ at least penetrates the second stacked structure layer 120a in the direction Z, and extend to the first stacked structure layer 110a to expose a portion of the first conductive layer 1161, but the disclosure is not limited thereto.

### Step (2′): Forming the at Least One Support Structure 400 in the at Least One Through Hole VC′

First, an insulating layer (not shown) is formed over the second stacked structure layer 120a by performing a suitable deposition process. The insulating layer is filled in the at least one through hole VC′. Next, a planarization process is performed to remove the insulating layer located on the top surface of the second stacked structure layer 120a. Hence, the at least one support structure 400 is formed in the at least one through hole VC′. In some embodiments, a material of the support structure 400 includes oxide, but the disclosure is not limited thereto. In other embodiments, the material of the support structure 400 is different from that of the first sacrificial layer 114 and the second sacrificial layer 124 to prevent the support structure 400 from being removed when performing a process for removing the first sacrificial layer 114 and the second sacrificial layer 124.

In some embodiments, a cover layer 130 is further formed on the stacked architecture layer 100a after the channel structure 200 and the at least one support structure 400 are formed in the stacked architecture layer 100a. The cover layer 130 may be formed by performing a chemical vapor deposition process or other suitable processes, but the disclosure is not limited thereto. In the present embodiment, the cover layer 130 covers the channel structure 200 and the at least one support structure 400, but the disclosure is not limited thereto. In some embodiments, a material of the cover layer 130 includes oxide.

At this point, the formation of the at least one support structure 400 is completed. Although the manufacturing method of the at least one support structure 400 of the present embodiment is explained by taking the above method as an example, the manufacturing method of the at least one support structure 400 provided by the disclosure is not limited thereto. It is worth mentioned that the sequence of formation between the at least one support structure 400 and the channel structure 200 is not limited. In some embodiments, the at least one support structure 400 and the channel structure 200 can be formed in the same process. Therefore, the material of the least one support structure 400 may be the same as the material the channel structure 200. However, the at least one support structure 400 does not provide a charge storage function as the channel structure 200 does.

In addition, referring to FIG. 1A, a plurality of dummy support structures 400′ are formed in the stacked architecture layer 100a between a first slit SLIT1 and a second slit SLIT2 in a step region SR in the present embodiment. The first slit SLIT1 and the second slit SLIT2 will be introduced in detail later. A method of forming the plurality of dummy support structures 400′ in the stacked architecture layer 100a includes the following steps, but the disclosure is not limited thereto.

### Step (1a): Forming a Plurality of Dummy Through Holes DVC

In some embodiments, a portion of the stacked architecture layer 100a is removed by performing a patterning process to form the plurality of dummy through holes DVC in the stacked architecture layer 100a between the first slit SLIT1 and the second slit SLIT2 in the step region SR. The patterning process can include a photolithography process and an etching process, but the disclosure is not limited thereto. The plurality of dummy through holes DVC at least penetrate second stacked structure layer 120a in the direction Z, and extend to the first stacked structure layer 110a, but the disclosure is not limited thereto.

### Step (2a): Forming the Plurality of Dummy Support Structures 400′ in the Plurality of Dummy Through Holes DVC

First, an insulating layer (not shown) is formed over the second stacked structure layer 120a by performing a suitable deposition process. The insulating layer is filled in the plurality of dummy through holes DVC. Next, a planarization process is performed to remove the insulating layer located on the top surface of the second stacked structure layer 120a. Hence, the plurality of dummy support structures 400′ are formed in the corresponding dummy through holes DVC. In some embodiments, a material of the plurality of dummy support structures 400′ includes silicon oxide, but the disclosure is not limited thereto. In other embodiments, the material of the plurality of dummy support structures 400′ is different from that of the first sacrificial layer 114 and the second sacrificial layer 124 to prevent the plurality of dummy support structures 400′ from being removed when performing a process for removing the first sacrificial layer 114 and the second sacrificial layer 124.

Referring to FIGS. 2B, 3B and 4B simultaneously, a slit SLIT is formed in the stacked architecture layer 100a after providing the stacked architecture layer 100a including the channel structure 200 and the at least one support structure 400. The slit SLIT extends downwards (may be along the direction Z) in the stacked architecture layer 100a and along one horizontal direction (the direction X in the present embodiment). In some embodiments, a portion of the stacked architecture layer 100a is removed by performing a patterning process to form the slit SLIT in the stacked architecture layer 100a. The patterning process can include a lithography process and an etching process, but the disclosure is not limited thereto. In the present embodiment, portions of the second stacked structure layer 120a and the first stacked structure layer 110a are sequentially removed by using an etching process. The first conductive layer 1161 in the first stacked structure layer 110a may serve as an etching stop layer. In detail, the etching process can be stopped after the portion of the first conductive layer 1161 is removed, so that the bottom of the slit SLIT expose a portion of the first conductive layer 1161.

In the present embodiment, the slit SLIT includes a first slit SLIT1 and a second slit SLIT2. The first slit SLIT1 and the second slit SLIT2 are parallel along the direction Y to define a plurality of memory blocks 10B of the 3D memory device 10, which will be described in the following embodiments. In the present embodiment, the first slit SLIT1 includes a plurality of discrete sub-slits SLIT1a. The plurality of discrete sub-slits SLIT1a are arranged along the direction X. In the present embodiment as shown in FIG. 1B, the plurality of discrete sub-slits SLIT1a are disposed between the first group of channel structures 200A and the second group of channel structures 200B. In addition, the at least one through hole VC′ is disposed between the adjacent discrete sub-slits SLIT1a as shown in FIG. 1A.

It is worth mentioned that a portion of the dielectric layer 122, a portion of the cover layer 130 and a portion of the second sacrificial layers 124 will be removed when forming the slit SLIT in the stacked architecture layer 100a.

Referring to FIGS. 2C, 3C and 4C simultaneously, the plurality of second sacrificial layers 124 in the second stacked structure layer 120a are removed to form a plurality of gate trenches GTr. Each of the plurality of gate trenches GTr exposes a portion of the charge storage structure 210. In detail, an etching process is performed to remove the plurality of sacrificial layers 124 exposed by the slit SLIT. In the present embodiment, the above etching process is a wet etching process using phosphoric acid as the etching liquid, but the disclosure is not limited thereto.

It is worth mentioned that a source line plane SL is further formed before removing the plurality of second sacrificial layers 124 in the second stacked structure layer 120a. In some embodiments, a method of forming the source line plane SL includes the following steps, but the disclosure is not limited thereto.

First, the first insulator 1121 and the second insulator 1122 and the first sacrificial layer 114 in the first stacked structure layer 110a adjacent to the bottom of the slit SLIT are removed. Also, a portion of the charge storage structure 210 is also removed at the same time. A lateral source line plane trench STr is formed in the above process, and the lateral source line plane trench STr exposes a portion of the channel layer 220 as shown in FIG. 3C. In detail, after the slit SLIT is formed, a protective layer (not shown) is formed on a sidewall of slit SLIT. The protective layer covers sidewalls of the plurality of dielectric layers 122 and the plurality of second sacrificial layers 124 in the second stacked structure layer 120a exposed by the slit SLIT. The protective layer also covers the second conductive layer 1162 in the first stacked structure layer 110a exposed by the slit SLIT. After that, an etching process is performed to remove the second conductive layer 1162, the first insulator 1121, the first sacrificial layer 114, the second insulator 1122, and the portion of the charge storage structure 210 in the channel structure 200 that are not covered by the protective layer. After the etching process is performed, the lateral source line plane trench STr is formed. It is worth mentioned that the above etching process can be a multi-stage etching process including the following steps, but the disclosure is not limited thereto.

After that, a source line plane SL is formed in the lateral source line plane trench STr. In some embodiments, a method of forming the source line plane SL includes the following steps, but the disclosure is not limited thereto. First, a conductive layer (not shown) is formed on the second stacked structure layer 120a by performing a suitable deposition process. The conductive layer is filled in the slit SLIT and the lateral source line plane trench STr. Next, the conductive layer located on the top surface of the second stacked structure layer 120a and located in the slit SLIT are removed by performing an etch-back process. Thus, a third conductive layer 116 is formed in the lateral source line plane trench STr. The above etch back process can remove a portion of the conductive layer located in the lateral source line plane trench STr and exposed by the slit SLIT, but the disclosure is not limited thereto. In some embodiments, a material of the third conductive layer 116 includes polysilicon, metal, or a combination thereof, but the disclosure is not limited thereto.

It is worth mentioned that a portion of the first conductive layer 1161 and a portion of the second conductive layer 1162 can be removed after performing the above etch back process. In the present embodiment, the source line plane SL including the third conductive layer 116 located in the lateral source line trench STr and the first conductive layer 1161 and the second conductive layer 1162 is formed. In other words, a first stacked structure 110 including the first conductive layer 1161, the third conductive layer 116 and the second conductive layer 1162 is formed in a location of the original first stacked structure layer 110a.

Referring to FIGS. 2D, 3D and 4D simultaneously, a conductive layer CL is formed in the plurality of gate trenches GTr, to form a second stacked structure 120. In some embodiments, a method of forming the conductive layer CL includes the following steps, but the disclosure is not limited thereto. First, a conductive layer (not shown) is formed by performing a suitable deposition process. The conductive layer is filled in the slit SLIT and the plurality of gate trenches GTr. Next, an etch-back process is performed to remove the conductive layer located in the slit SLIT to form a plurality of the conductive layers CL in the plurality of gate trenches GTr. Also, the second stacked structure 120 is formed. In other words, the second stacked structure 120 including the plurality of conductive layers CL and the plurality of dielectric layers 122 alternately disposed is formed. In some embodiments, a material of the conductive layer CL includes polysilicon, metal, or a combination thereof, but the disclosure is not limited thereto.

In the present embodiment, the plurality of conductive layers CL may include a plurality of word lines WL, a string select line SSL and a ground select line GSL. The plurality of word lines WL are stacked in the direction Z and located between the string select line SSL and the ground select line GSL. It is worth mentioned that FIGS. 2D, 3D and 4D show the plurality of conductive layers CL includes one string select line SSL and one ground select line GSL, but the disclosure is not limited thereto. Based on the above, one memory cell can be defined by one channel structure 200 surrounded by one of the plurality of word lines WL after the plurality of conductive layers CL are formed. For example, FIG. 2D shows that a memory cell MC can be defined by the word line WL surrounding the corresponding channel structure 200, but the disclosure is not limited thereto. In addition, a string select transistor (not shown) and a ground select transistor (not shown) can be respectively defined by the string select line SSL and the ground select line GSL surrounding the corresponding channel structure 200.

Referring to FIGS. 2D, 3D and 4D continuously, a separation structure 300 (e.g. the first partition structure 310 and the second partition structure 320) is formed in the slit SLIT. In some embodiments, a method of forming the separation structure 300 includes the following steps, but the disclosure is not limited thereto. First, an insulating layer is respectively formed on the sidewalls of the slit SLIT by performing a suitable deposition process. Next, a suitable deposition process is performed to respectively fill in the slit SLIT, so as to form the separation structure 300 which acts as a source plane contact (e.g. a first source plane contact 314 and a second source plane contact 324) electrically connected to the source line plane SL. The insulating layer is used to electrically isolate the source plane contact from the conductive layer CL. In some embodiments, a material of the insulating layer includes silicon oxide, and a material of the source plane contact includes a conductive material such as polysilicon, metal, or a combination thereof, but the disclosure is not limited thereto.

In the present embodiment as shown in FIGS. 1B and 4D, the separation structure 300 includes a plurality of first partition structures 310 and a plurality of second partition structures 320. One of the plurality of first partition structures 310 includes a first isolation layer 312 and a first source plane contact 314, and one of the plurality of second partition structures 320 includes a second isolation layer 322 and a second source plane contact 324. In one embodiment, a material of a material of the second source plane contact 324 is the same as the material of the first source plane contact 314. The plurality of first partition structures 310 extend along the direction X, and are each disposed in the corresponding slit SLIT (e.g. the first slit SLIT1 and the second slit SLIT2). In detail, one of the plurality of first partition structures 310 includes a plurality of discrete partition structures 310a respectively disposed in the corresponding discrete sub-slits SLIT1a. The plurality of second partition structures 320 extend continuously along the direction X, and are each disposed in the corresponding continuous second slit SLIT2. In some embodiments, the plurality of first partition structures 310 and the plurality of second partition structures 320 are alternately arranged in the direction Y to define the memory block 10B of the 3D memory device 10, but the disclosure is not limited thereto. In the present embodiment, the plurality of discrete partition structures 310a and the plurality of second partition structures 320 are disposed between the corresponding first group of channel structures 200A and the corresponding second group of channel structures 200B. In detail, the plurality of second partition structures 320 are disposed at a first side of the first group of channel structures 200A and extend continuously along the direction X, and the plurality of first partition structures 310 are disposed at a second side of the first group of channel structures 200A.

At this point, the forming of 3D memory device 10 is completed. Although the manufacturing method of 3D memory device 10 of the present embodiment is explained by taking the above method as an example, the manufacturing method of the 3D memory device provided by the disclosure is not limited thereto.

In the manufacturing method of the 3D memory device 10 provided in the present embodiment, the at least one support structure 400 penetrating the plurality of dielectirc layers 122 is disposed between the adjacent discrete partition structures 310a (or the adjacent sub-slits SLIT1a) which would be formed in the subsequent process. Based on the above, during the formation of the plurality of conductive layers CL, the collapse phenomenon of the plurality of dielectric layers 122 located between the adjacent discrete partition structures 310a can be avoided after removing of the plurality of second sacrificial layers 124. Therefore, the 3D memory device 10 provided in the present embodiment could be improved.

The structure of the 3D memory device 10 of the present embodiment will be briefly introduced below with reference to FIGS. 1A, 1B, 2D, 3D and 4D, but the disclosure is not limited thereto.

Referring to FIGS. 1A, 1B, 2D, 3D and 4D, the 3D memory device 10 provided by the disclosure can be a 3D NAND flash memory, but the disclosure is not limited thereto. The 3D memory device 10 includes a plurality of memory blocks 10B, wherein the plurality of memory blocks 10B can be defined by the separation structure 300, but the disclosure is not limited thereto. It is worth mentioned that FIG. 1A only shows that the 3D memory device 10 includes four memory blocks 10B as an example, but the disclosure is not limited thereto.

In the present embodiment, the 3D memory device 10 includes a stacked architecture 100, a channel structure 200, a separation structure 300 and at least one support structure 400.

As illustrated in FIG. 4D, the stacked architecture 100 includes a first stacked structure 110 and a second stacked structure 120, and the second stacked structure 120 is disposed on the first stacked structure 110.

The first stacked structure 110 includes a first conductive layer 1161, a third conductive layer 116 and a second conductive layer 1162 stacked in the direction Z. In the present embodiment, the first conductive layer 1161, the third conductive layer 116 and the second conductive layer 1162 are serve as a source line plane SL of the 3D memory device 10. The remaining technical contents pertaining the first conductive layer 1161, the third conductive layer 116 and the second conductive layer 1162 can refer to the above embodiments, and will be omitted herein.

The second stacked structure 120 includes a plurality of conductive layers CL and a plurality of dielectric layers 122 alternately stacked in the direction Z. In one embodiment, a top surface of the second stacked structure 120 is parallel to the plane defined by the directions X and Y.

The plurality of conductive layers CL extend on a plane defined by a direction X and a direction Y, which are orthogonal to the direction Z. In the present embodiment, a length of each conductive layers CL in the direction X becomes longer when getting closer to the substrate SB along the direction Z, so that the plurality of conductive layers CL can be formed to have a ladder structure in a step region SR as shown in FIG. 1A. The remaining technical contents pertaining the plurality of conductive layers CL can refer to the above embodiments, and will be omitted herein.

The plurality of dielectric layers 122 also extend on the plane defined by the direction X and the direction Y. The remaining technical contents pertaining the plurality of dielectric layers 122 can refer to the above embodiments, and will be omitted herein.

The channel structure 200 extends along the direction Z and penetrates the second stacked structure 120. Namely, the channel structure 200 penetrates from a top surface of the second stacked structure 120 to a bottom surface of the second stacked structure 120. The channel structure 200 includes a memory cell string. Each memory cell in the memory cell string is electrically connected to the corresponding word line WL, but the disclosure is not limited thereto. In the present embodiment, the channel structure 200 includes a charge storage structure 210, a channel layer 220, an insulating pillar 230 and a conductive plug 240, but the disclosure is not limited thereto.

The charge storage structure 210 surrounds the channel layer 220, which can be an external structure of the channel structure 200. In some embodiments, the charge storage structure 210 can include a composite layer. The charge storage structure 210 includes three dielectric layers sequentially stacked on the side surface of the channel layer 220. For example, the charge storage structure 210 includes a composite layer of oxide-nitride-oxide (ONO), but the disclosure is not limited thereto. In other embodiments, the charge storage structure 210 can include a composite layer of oxide-nitride-oxide-nitride-oxide (ONONO) or a composite layer including other structures. In the present embodiment, the charge storage structure 210 includes a tunneling layer (not shown), a charge storage layer (not shown), and a blocking layer (not shown) surrounding the channel layer 220 in this sequence. The remaining technical contents pertaining the charge storage structure 210 can refer to the above embodiments, and will be omitted herein.

Based on the above, a plurality of memory cells can each be defined by the channel structure 200 surrounded by the plurality of word lines WL. For example, a memory cell MC shown in FIG. 2D is respectively defined by the bottommost word line in the plurality of word lines WL surrounding the channel structure 200. In some embodiments, the plurality of memory cells can perform 1-bit operations or 2-bit operations through different operation methods. For example, when a voltage is applied to the channel structure 200, charges can be transported along the channel layer 220 and stored in the charge storage structure 210. The plurality of memory cells can be operated in the single-level cell (SLC; 1 bit) mode or the multi-level cell (MLC; greater than or equal to 2 bits) mode, but the disclosure is not limited thereto.

The channel layer 220 has a ring structure in the direction Z. The remaining technical contents pertaining the channel layer 220 can refer to the above embodiments, and will be omitted herein.

The insulating pillar 230 is surrounded by the channel layer 220. Namely, the insulating pillar 230 is disposed inside the channel layer 220, and extends along the direction Z. The remaining technical contents pertaining the insulating pillar 230 can refer to the above embodiments, and will be omitted herein.

The conductive plug 240 is disposed over the insulating pillar 230 and is also surrounded by the channel layer 220. In some embodiments, the conductive plug 240 is electrically connected to the channel layer 220. The remaining technical contents pertaining the conductive plug 240 can refer to the above embodiments, and will be omitted herein.

The separation structure 300 (e.g. the first partition structure 310 and the second partition structure 320) is disposed over the substrate SB and penetrates the second stacked structure 120. In the present embodiment as illustrated in FIGS. 1A, 1B and 4D, the separation structure 300 includes a plurality of first partition structures 310 and a plurality of second partition structures 320. One of the plurality of first partition structures 310 includes a plurality of discrete partition structures 310a arranged along the direction X. The plurality of second partition structures 320 extend continuously along the direction X. A length of the second partition structure 320 is greater than a sum of lengths of the plurality of discrete partition structures 310a of the first partition structure 310. In some embodiments, the plurality of first partition structures 310 and the plurality of second partition structures 320 are alternately arranged in the direction Y to define the plurality of memory blocks 10B of the 3D memory device 10. For example, as shown in FIG. 1A, the adjacent partition structures 310 and 320 can be used to define one memory block 10B, but the disclosure is not limited thereto. In the present embodiment, the plurality of discrete partition structures 310a and the plurality of second partition structures 320 are disposed between the corresponding first group of channel structures 200A and the corresponding second group of channel structures 200B. The remaining technical contents pertaining the separation structure 300 can refer to the above embodiments, and will be omitted herein.

The at least one support structure 400 is disposed between the adjacent discrete partition structures 310a. In detail, referring to FIG. 1B, the at least one support structure 400 is disposed between the adjacent discrete partition structures 310a in the direction X. In the present embodiment, the material of the at least one support structure 400 is the same as the material of the blocking layer of the charge storage structure 210, for example, an oxide layer. In other embodiments, the material of the at least one supporting structure 400 is the same as the material of the insulating pillar 230 of the channel structure 200, for example, an oxide layer, but the disclosure is not limited thereto. In another embodiments, the material of the at least one supporting structure 400 is different from the material of the first source plane contact 314 of the discrete partition structure 310a of the first partition structure 310.

There is a distance D1 between one of the at least one support structure 400 and a closest channel structure in one of the first group of channel structures 200A and the second group of channel structures 200B. When the distance D1 is less than 20 nm, the conductive layer CL located between the support structure 400 and the closest channel structure in one of the first group of channel structures 200A and the second group of channel structures 200B may crack. When the distance D1 is greater than 400 nm, the plurality of dielectric layers 122 located between the adjacent discrete partition structures 310a may collapse. Therefore, in some embodiments, the distance D1 between one of the at least one support structure 400 and the closest channel structure in one of the first group of channel structures 200A and the second group of channel structures 200B is 20 nm to 400 nm. In other embodiments, the distance D1 between one of the at least one support structure 400 and the closest channel structure in one of the first group of channel structures 200A and the second group of channel structures 200B is 20 nm to 100 nm.

There is a distance D2 between one of the at least one support structure 400 and a closest one of the plurality of discrete partition structures 310a. When the distance D2 is less than 20 nm, the conductive layer CL located between the support structure 400 and the closest discrete partition structure 310a may crack. When the distance D2 is greater than 400 nm, the plurality of dielectric layers 122 located between the adjacent discrete partition structures 310a may collapse. Therefore, in some embodiments, the distance D2 between one of the at least one support structure 400 and the closest one of the plurality of discrete partition structures 310a is 20 nm to 400 nm.

A shape of the at least one support structure 400 in the direction Z of the 3D memory device 10 includes a circle, a rectangle, an ellipse, or a combination thereof. In the present embodiment, the shape of the at least one support structure 400 in the direction Z of the 3D memory device 10 is a circle, but the disclosure is not limited thereto. In one embodiment, a width (or diameter) of the at least one support structure 400 is in a range from 100 nm to 360 nm. A width (or diameter) of the channel structure 200 is in a range from 100 nm to 130 nm. A ratio of the width (or diameter) of the at least one support structure 400 to the width (or diameter) of the channel structure 200 is in a range from 1 to 3. With this ratio, the mechanical strength of the plurality of dielectric layers 122 may be enhanced to prevent collapse of the dielectric layers 122 during the formation of the plurality of conductive layers CL. Hence, the reliability of the 3D memory device 10 may be improved.

The remaining technical contents pertaining the at least one support structure 400 can refer to the above embodiments, and will be omitted herein.

Referring to FIG. 1A, the 3D memory device 10 of the present embodiment has an array region AR and a step region SR. The channel structure 200 is disposed in the array region AR. In detail, in the present embodiment, the first group of channel structures 200A and the second group of channel structures 200B in the channel structure 200 are disposed over the substrate SB in the array region AR. In some embodiments, the word line WL may extend from the step region SR to the array region AR, but the disclosure is not limited thereto. The arrangement of the step region SR can be used to electrically connect the components (such as memory cells) located in the array region AR to a driving circuit layer (not shown) through a plurality of contact windows (not shown) and a plurality of electrical connectors (not shown), but the disclosure is not limited thereto.

In detail, the plurality of contact windows may be disposed in the step region SR and extend along the direction Z to be electrically connected to the corresponding conductive layer CL and the driving circuit layer. The plurality of electrical connectors may be disposed in the step region SR and extend along the direction Y, so as to be electrically connected to the corresponding contact window. Based on the above, the components (such as memory cells) located in the array region AR can be electrically connected to the driving circuit layer through the plurality of contact windows and the plurality of electrical connectors.

In the present embodiment, the 3D memory device 10 further includes at least one dummy support structure 400′.

The number of the at least one dummy supporting structure 400′ is multiple. Referring to FIG. 1A, the plurality of dummy support structures 400′ are disposed in the step region SR. In some embodiments, the plurality of dummy support structures 400′ are arranged in an array pattern, but the disclosure is not limited thereto. In the present embodiment, the plurality of dummy support structures 400′ are electrically floating or not electrically connected to other external power sources. The density of the plurality of dummy support structures 400′ may be smaller than the density of the at least one support structure 400 disposed in the step region AR, but the disclosure is not limited thereto. In some embodiments, a material of the at least one dummy support structure 400′ is the same as a material of the at least one support structure 400. The plurality of dummy supporting structures 400′ may be used to support the strength of the stacked architecture 100 located in the step region SR to prevent the stacked architecture 100 from being collapsed during the formation process.

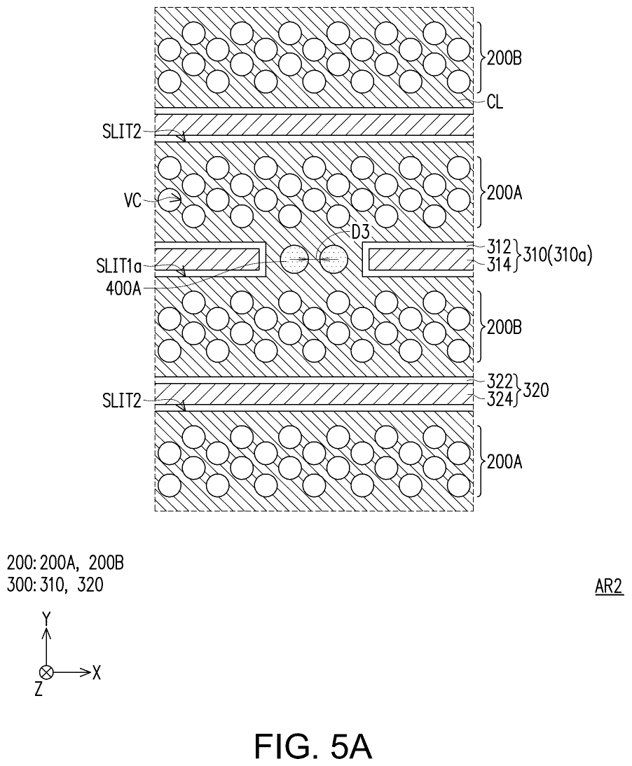

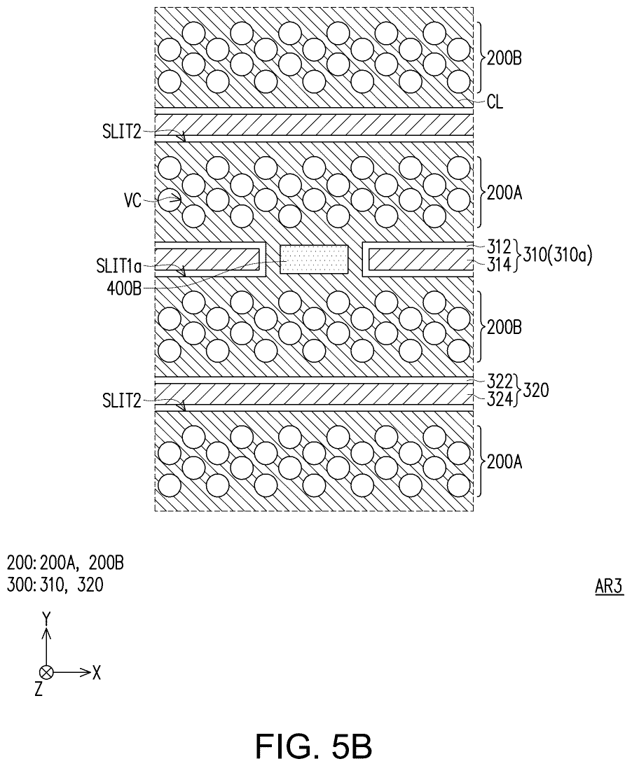

FIG. 5A shows an enlarged top view of a second embodiment of an array region AR2 according to FIG. 1A, and FIG. 5B shows an enlarged top view of a third embodiment of an array region AR3 according to FIG. 1A. It should be noted that the embodiment of FIGS. 5A-5B can respectively use the reference numbers and portions of the content of the above embodiment of FIG. 1B, the same or similar reference numbers are used to represent the same or similar elements, and descriptions of the same technical contents are omitted.

Referring to FIG. 5A, the main difference between the present embodiment and the embodiment shown in FIG. 1B is that the number of at least one support structure 400A is two, but the disclosure is not limited thereto. In other embodiments, the number of the at least one support structure 400A may be more than two.

In the present embodiment, a distance D3 between the two adjacent support structures 400A is less than or equal to 400 nm, but the disclosure is not limited thereto.

Referring to FIG. 5B, the main difference between the present embodiment and the embodiment shown in FIG. 1B is that a shape of at least one support structure 400B in the direction Z of the 3D memory device 10 is a rectangle, but the disclosure is not limited thereto.

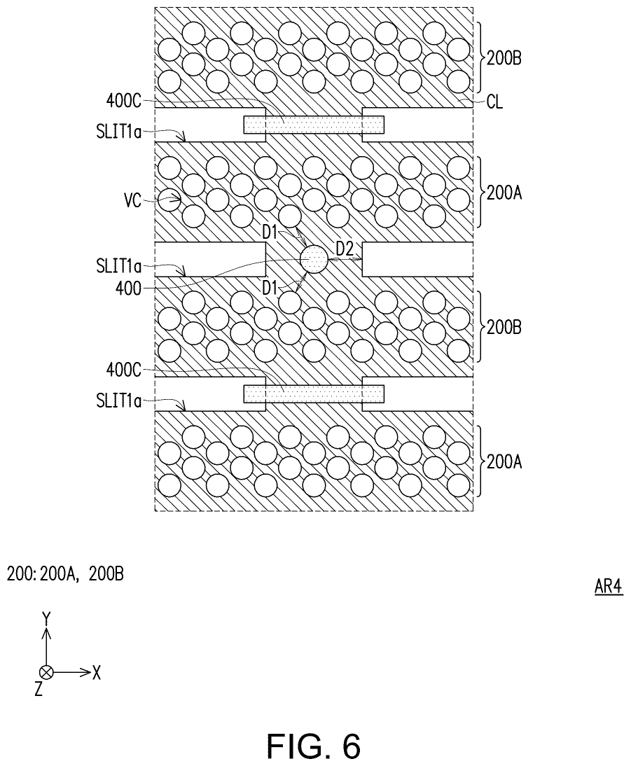

FIG. 6 shows an enlarged top view of a fourth embodiment of an array region AR4 according to FIG. 1A. It should be noted that the embodiment of FIG. 6 can use the reference numbers and portions of the content of the above embodiment of FIG. 1B, the same or similar reference numbers are used to represent the same or similar elements, and descriptions of the same technical contents are omitted.

Referring to FIG. 6, the main difference between the present embodiment and the embodiment shown in FIG. 1B is that the 3D memory device 10 also includes a plurality of support structures 400C.

The plurality of support structures 400C extend along the direction X. In the present embodiment, one of the plurality of support structures 400C partially overlaps at least one sub-slit SLIT1a. In detail, at least one of two ends of the support structure 400C may overlap with the corresponding sub-slit SLIT1a, but the disclosure is not limited thereto. The collapse phenomenon of the stacked architecture 100 during the formation process can be further avoided through the plurality of support structures 400C.

In summary, in the 3D memory device provided by the disclosure, the at least one support structure is disposed between the adjacent discrete partition structures. Therefore, the plurality of dielectric layers located between the adjacent discrete partition structures can have a stable structure, which makes the 3D memory device of the disclosure have relatively high reliability.

In the manufacturing method of the 3D memory device provided by the disclosure, the at least one support structure penetrating the plurality of dielectric layers is disposed between the adjacent discrete partition structures which would be formed in the subsequent process. Based on the above, during the formation of the plurality of conductive layers, the collapse phenomenon of the plurality of dielectric layers located between the adjacent discrete partition structures can be avoided after removing of the plurality of sacrificial layers. Therefore, the 3D memory device manufactured by the manufacturing method by the disclosure could be improved.

Furthermore, in the manufacturing method of the 3D memory device provided by the disclosure, the at least one support structure and the oxide layer of the charge storage structure may be formed in the same process. Based on the above, the at least one support structure can be formed in the 3D memory device without the increase of manufacturing costs and/or process difficulties.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A 3D memory device, including:
a stacked structure, including a plurality of conductive layers and a plurality of dielectric layers stacked alternately, wherein a top surface of the stacked structure is parallel to a plane defined by a first direction and a second direction;
a first group of channel structures and a second group of channel structures, penetrating the stacked structure and arranged along the first direction;
a first partition structure, including a plurality of discrete partition structures disposed between the first group of channel structures and the second group of channel structures, wherein the plurality of discrete partition structures are arranged along the second direction and penetrate the stacked structure; and
at least one support structure, disposed between the adjacent discrete partition structures.

2. The 3D memory device according to claim 1, wherein a distance between one of the at least one support structure and a closest channel structure in one of the first group of channel structures and the second group of channel structures is 20 nm to 400 nm.

3. The 3D memory device according to claim 1, wherein a distance between one of the at least one support structure and a closest channel structure in one of the first group of channel structures and the second group of channel structures is 20 nm to 100 nm.

4. The 3D memory device according to claim 1, wherein a distance between one of the at least one support structure and a closest one of the plurality of discrete partition structures is 20 nm to 400 nm.

5. The 3D memory device according to claim 1, wherein the number of the at least one supporting structure is two or more.

6. The 3D memory device according to claim 5, wherein a distance between the adjacent supporting structures is less than or equal to 400nm.

7. The 3D memory device according to claim 1 further comprising:
a second partition structure, disposed at a first side of the first group of channel structures and extending continuously along the second direction, and the first partition structure disposed at a second side of the first group of channel structures.

8. The 3D memory device according to claim 7, wherein a length of the second partition structure is greater than a sum of lengths of the plurality of discrete partition structures of the first partition structure.

9. The 3D memory device according to claim 1, wherein a material of the at least one support structure is the same as a material of an insulating pillar of one channel structure among the first group of channel structures and the second group of channel structures.

10. The 3D memory device according to claim 1, wherein a material of the at least one support structure is different from a material of a source plane contact of one of the plurality of the discrete partition structures.

11. The 3D memory device according to claim 1, wherein a ratio of a width or diameter of the at least one support structure to a width or diameter of the channel structure is in a range from 1 to 3.

12. The 3D memory device according to claim 1, wherein the substrate includes an array region and a step region, and the first group of channel structures and the second group of channel structures are disposed in the array region.

13. The 3D memory device according to claim 12, further including at least one dummy support structure disposed in the step region.

14. The 3D memory device according to claim 13, wherein the at least one dummy support structure includes a plurality of dummy support structures arranged in an array pattern.

15. The 3D memory device according to claim 13, wherein a material of the at least one dummy support structure is the same as a material of the at least one support structure.

16. The 3D memory device according to claim 1, further including:
a third partition structure, including a plurality of discrete partition structures disposed at a side of the second group of channel structures.

17. A 3D memory device, including:
a first stacked structure, including a source line plane; and
a second stacked structure, disposed over the first stacked structure and including a plurality of conductive layers and a plurality of dielectric layers stacked alternately;
a first group of channel structures and a second group of channel structures, penetrating the second stacked structure and arranged along a first direction;
a separation structure, including:
a first partition structure, including a plurality of discrete partition structures disposed between the first group of channel structures and the second group of channel structures, wherein the plurality of discrete partition structures are arranged along a second direction different from the first direction and penetrate the second stacked structure; and
a second partition structure, extending continuously along the second direction and penetrating the second stacked structure, wherein the second partition structure and the first partition structure are parallel along the first direction; and
at least one support structure, disposed between the adjacent discrete partition structures.

18. The 3D memory device according to claim 17, wherein a material of the at least one support structure is the same as a material of an insulating pillar of one channel structure among the first group of channel structures and the second group of channel structures.

19. The 3D memory device according to claim 17, wherein a distance between one of the at least one support structure and a closest channel structure in one of the first group of channel structures and the second group of channel structures is 20 nm to 400 nm.

20. The 3D memory device according to claim 17, wherein a distance between one of the at least one support structure and a closest one of the plurality of discrete partition structures is 20 nm to 400 nm.
